(19) United States
(12) Patent Application Publication
(10) Pub. No.: US 2023/0227971 A1
(43) Pub. Date: Jul. 20, 2023

(54) DEPOSITION APPARATUS AND METHOD OF CLEANSING THE SAME

(71) Applicant: Samsung Display Co., LTD., Yongin-si (KR)

(72) Inventors: JONGBUN HAN, Hwaseong-si (KR); JUHEE LEE, Hwaseong-si (KR); Suk Won JUNG, Sejong-si (KR); Sang Jin HAN, Seoul (KR)

(73) Assignee: Samsung Display Co., LTD., Yongin-si (KR)

(21) Appl. No.: 18/080,935

(22) Filed: Dec. 14, 2022

(30) Foreign Application Priority Data
Jan. 18, 2022 (KR) 10-2022-0007482

(51) Int. Cl. C23C 16/44; H01J 37/32; B08B 5/00; B08B 13/00

(52) U.S. Cl. CPC C23C 16/4405; H01J 37/32449; H01J 37/32862; H01J 37/32816; B08B 5/00; B08B 13/00; H01J 2237/24585; H01J 2237/186; H01J 37/32633; H01J 2237/182

(57) ABSTRACT

An embodiment provides a deposition apparatus, including: a process chamber; a residual gas analyzer connected to the process chamber; a cleansing gas supplier connected to the process chamber; and a driver that is connected to the residual gas analyzer and the cleansing gas supplier and controls the residual gas analyzer and the cleansing gas supplier.

### CROSS-REFERENCE TO RELATED APPLICATION(S)

This application claims priority to and benefits of Korean Patent Application No. 10-2022-0007482 under 35 U.S.C. § 119, filed on Jan. 18, 2022, in the Korean Intellectual Property Office (KIPO), the entire contents of which are incorporated herein by reference.

### BACKGROUND

### 1. Technical Field

Embodiments relate to a deposition apparatus and a method of cleansing the deposition apparatus.

### 2. Description of the Related Art

Display devices include a liquid crystal display (LCD), a plasma display panel (PDP), an organic light emitting diode (OLED) device, a field emission display (FED), and an electrophoretic display device.

The display device may include a plurality of layers, such as a plurality of signal lines and emission layers, and the plurality of layers may be manufactured by being stacked by using a thermal deposition source in a vacuum environment.

In case that unnecessary internal contaminants remain in a chamber of a deposition apparatus used for a deposition process, a vacuum degree in the chamber is lowered by an internal compound, or a moisture content in the chamber is increased, so quality of a deposited thin film may be degraded.

The above information disclosed in this Background section is only for enhancement of understanding of the background of the described technology, and therefore it may contain information that does not form the prior art that is already known in this country to a person of ordinary skill in the art.

### SUMMARY

Embodiments provide a deposition apparatus and a method of cleansing the deposition apparatus. For example, the method of cleansing the deposition apparatus is capable of improving quality of a thin film deposited in the deposition apparatus by measuring a content of a residual organic material in the deposition apparatus and by performing a process of removing the residual organic material.

However, embodiments of the disclosure are not limited to those set forth herein. The above and other embodiments will become more apparent to one of ordinary skill in the art to which the disclosure pertains by referencing the detailed description of the disclosure given below.

In an embodiment, a deposition apparatus may include: a process chamber; a residual gas analyzer connected to the process chamber; a cleansing gas supplier connected to the process chamber; and a driver connected to the residual gas analyzer and the cleansing gas supplier, the driver that controls the residual gas analyzer and the cleansing gas supplier.

The driver may control an operation of the cleansing gas supplier based on data received from the residual gas analyzer.

The deposition apparatus may further include: a dry pump connected to the process chamber; and a pressure control valve connected between the process chamber and the dry pump.

The deposition apparatus may further include an on-off valve connected between the process chamber and the pressure control valve.

The deposition apparatus may further include: a first valve connected between the process chamber and the residual gas analyzer; and a second valve connected between the process chamber and the cleansing gas supplier.

The residual gas analyzer and the cleansing gas supplier may be connected to or disconnected from the process chamber by the first valve and the second valve.

The residual gas analyzer and the cleansing gas supplier may be connected to a side of the process chamber.

The deposition apparatus may further include a baffle adjacent to the cleansing gas supplier.

The cleansing gas supplier may be a plasma generator.

The cleansing gas supplier may supply oxygen radicals.

The cleansing gas supplier may be an ozone generator.

In an embodiment, a method of cleansing a deposition apparatus may include: measuring a concentration of a residual gas in a process chamber; determining, by a driver, whether a cleansing process of the process chamber performed based on the measured concentration of the residual gas; supplying a cleansing gas to the process chamber to cleanse it; and re-measuring a concentration of the residual gas in the cleansed process chamber.

The method of cleansing the deposition apparatus may further include transmitting the measured concentration of the residual gas to the driver.

In case that the driver determines to perform the cleansing process, the cleansing process of the process chamber and the re-measuring of the concentration of the residual gas in the cleansed process chamber may be performed.

In case that the driver determines not to perform the cleansing process, the cleansing process of the process chamber and the re-measuring of the concentration of the residual gas in the cleansed process chamber may be stopped.

The supplying of the cleansing gas may include supplying oxygen radicals to the process chamber.

The supplying of the cleansing gas may include supplying an inert gas together with the cleansing gas.

The inert gas may include nitrogen gas or argon.

The supplying of the cleansing gas may include supplying ozone to the process chamber.

A pressure of the process chamber may be maintained to be substantially constant during the cleansing process of the process chamber by a pressure control valve connected between the process chamber and a dry pump.

According to the deposition apparatus and the method of cleansing the deposition apparatus according to embodiments, it is possible to maintain quality of a thin film deposited by measuring a content of an unnecessary organic material in a process chamber and performing a process of removing the unnecessary organic material.

It is obvious that the effect of the embodiments is not limited to the above-described effect, and may be variously extended without departing from the spirit and scope of the embodiments.

### BRIEF DESCRIPTION OF THE DRAWINGS

FIG. 1 illustrates a schematic block diagram of a deposition apparatus according to an embodiment.

FIG. 2 illustrates a schematic block diagram of a deposition apparatus according to an embodiment.

FIG. 3 illustrates a schematic block diagram of a deposition apparatus according to an embodiment.

FIG. 4 illustrates a schematic block diagram of a deposition apparatus according to an embodiment.

FIG. 5 illustrates a schematic block diagram of a deposition apparatus according to an embodiment.

FIG. 6 illustrates a flowchart illustrating a method of cleansing a deposition apparatus according to an embodiment.

### DETAILED DESCRIPTION OF THE EMBODIMENTS

The embodiments will be described more fully hereinafter with reference to the accompanying drawings, in which embodiments are shown. As those skilled in the art would realize, the described embodiments may be modified in various different ways, all without departing from the spirit or scope of the embodiments.

In order to clearly describe the embodiments, parts or portions that are irrelevant to the description are omitted, and identical or similar constituent elements throughout the specification are denoted by the same reference numerals.

Further, the accompanying drawings are provided only in order to allow embodiments disclosed in the specification to be easily understood and are not to be interpreted as limiting the spirit disclosed in the specification, and it is to be understood that the embodiments include all modifications, equivalents, and substitutions without departing from the scope and spirit of the embodiments.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other. To this end, the term “connected” may refer to physical, electrical, and/or fluid connection, with or without intervening elements. To this end, the term “connected” may refer to physical, electrical, and/or fluid connection, with or without intervening elements.

Hereinafter, various embodiments and variations will be described in detail with reference to the drawings.

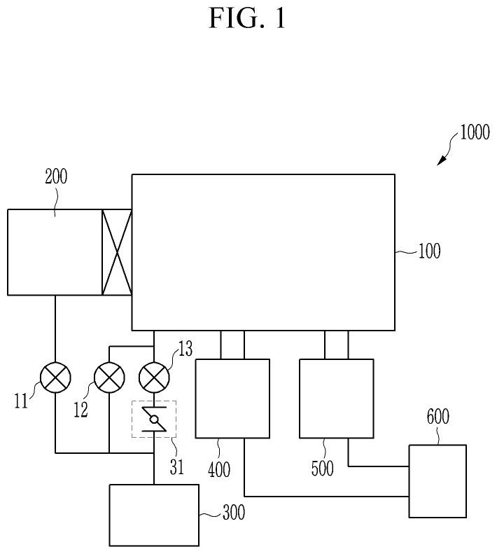

Referring to FIG. 1, a deposition apparatus 1000 according to an embodiment will be described. FIG. 1 illustrates a schematic block diagram of a deposition apparatus according to an embodiment.

Referring to FIG. 1, a deposition apparatus 1000 according to an embodiment may include a process chamber 100 in which a process for a deposition target substrate is performed, a cryopump 200 connected to the process chamber 100, a dry pump 300 connected to the process chamber 100, a residual gas analyzer (RGA) 400 connected to the process chamber 100, a cleansing gas supplier 500 connected to the process chamber 100, and a driver 600 connected to the residual gas analyzer 400 and the cleansing gas supplier 500. For example, the cryopump 200 may be a cryogenic pump or a vacuum pump. The cryopump 200 may trap gasses and vaporous by condensing the gasses and the vaporous on a cold surface. For example, the dry pump 300 may be a dry vacuum pump. The dry pump 300 may not use any fluids to create a vacuum or contact the process gas and may discharge to atmosphere.

A first valve 11 may be connected between the cryopump 200 and the dry pump 300, and a second valve 12 may be connected between the process chamber 100 and the dry pump 300.

For example, a third valve 13 and a pressure control valve 31 may be connected between the process chamber 100 and the dry pump 300. The pressure control valve 31 may be a throttle valve.

The first valve 11, the second valve 12, and the third valve 13 connected to the process chamber 100 may be connected to different pipes, in case that the first valve 11, the second valve 12, and the third valve 13 are not connected to each other.

The third valve 13 and the pressure control valve 31 connected to the process chamber 100 may be connected in series to the same pipe. For example, the third valve 13 may be connected between the process chamber 100 and the pressure control valve 31, and the pressure control valve 31 may be connected between the third valve 13 and the dry pump 300.

After performing a deposition process by using the process chamber 100, or before preforming the deposition process, a chamber cleansing process (e.g., a cleansing process of the process chamber 100) may be performed. For example, in case that the vacuum reaching time (or vacuum settling time) increases by measuring a vacuum reaching time in the process chamber 100, or in case that an amount of outgas discharged from the process chamber 100 increases by using the residual gas analyzer 400 in the process chamber 100, the chamber cleansing process may be performed.

In case that the chamber cleansing process (e.g., a cleansing process of the process chamber 100) is performed, the presence and concentration of residual gas in the process chamber 100 may be measured by using the residual gas analyzer 400 connected to the process chamber 100, and a measurement result of the residual gas analyzer 400 may be transmitted to the driver 600.

The residual gas analyzer 400 may measure or detect a low mass organic material to a high mass organic material.

The driver 600 may receive the measurement result of the residual gas analyzer 400, and remove (e.g., selectively remove) the residual gas in the process chamber 100 by using the cleansing gas supplier 500. The cleansing gas supplier 500 may supply cleansing gas to the process chamber 100. For example, the cleansing gas supplier 500 may be a gas activating device, so the cleansing gas supplier 500 may generate plasma. The cleansing gas supplier 500 may generate oxygen radicals and supply the oxygen radicals into the process chamber 100. The cleansing gas supplied from the cleansing gas supplier 500 may be a mixture of nitrogen (N₂) and an inert gas such as argon (Ar) together with oxygen radicals.

The oxygen radicals supplied into the process chamber 100 from the cleansing gas supplier 500 may react with a hydrocarbon (CₙHₘ), which is an organic material remaining inside the process chamber 100, and thus gases such as hydrogen (H₂), water (H₂O), and carbon monoxide (CO) may be generated, and the generated gases may be discharged to the outside of the process chamber 100.

In case that the residual gas removing step using the cleansing gas supplier 500 is performed, the driver 600 may use (e.g. control) the residual gas analyzer 400 to measure the residual gas in the process chamber 100. For example, the driver 600 may maintain an operation of the cleansing gas supplier 500 in case that a concentration of the residual gas in the process chamber 100 is larger than or equal to a predetermined value based on data (e.g., the measured result) received from the residual gas analyzer 400. For example, the operation of the cleansing gas supplier 500 may be stopped in case that the concentration of the residual gas in the process chamber 100 is smaller than a predetermined value, thereby stopping the chamber cleansing process (e.g., a cleansing process of the process chamber 100).

During the cleansing process of the process chamber 100, the first valve 11 and the second valve 12 connected to the process chamber 100 may be in a closed state, and the third valve 13 may maintain an opened state. As described above, the pressure control valve 31 may be connected between the third valve 13 and the dry pump 300, and through the pressure control valve 31, a desired pressure may be maintained inside the process chamber 100 during the cleansing process.

As described above, the deposition apparatus 1000 according to an embodiment may include the residual gas analyzer 400 and the cleansing gas supplier 500 connected to the process chamber 100, and the driver 600 connected to the residual gas analyzer 400 and the cleansing gas supplier 500. According to the deposition apparatus 1000 according to an embodiment, the residual gas concentration and the like in the process chamber 100 may be measured by using the residual gas analyzer 400, and the driver 600 may use (e.g. control) the measured value of the residual gas analyzer 400 to determine whether residual gas is removed or not (or whether removal of the residual gas is necessary). For example, when the removal of the residual gas is determined, a removal process of the residual gas using the cleansing gas supplier 500 may be performed. For example, the driver 600 may analyze the measured result of the residual gas analyzer 400 to determine whether to proceed or stop the operation of the cleansing gas supplier 500. For example, the process of monitoring the residual gas inside the process chamber 100 and simultaneously using the result to remove the residual gas through the cleansing gas supplier 500 may be performed in-situ, so that the cleansing process may be quickly and accurately performed.

For example, since the deposition apparatus 1000 according to an embodiment includes the pressure control valve 31 connected between the third valve 13 connected to the process chamber 100 and the dry pump 300, the inside state of the process chamber 100 may be adjusted with being maintained at a desired pressure during the cleansing process through the pressure control valve 31. Thus, the efficiency of the process of removing residual gas inside the process chamber 100 may be increased.

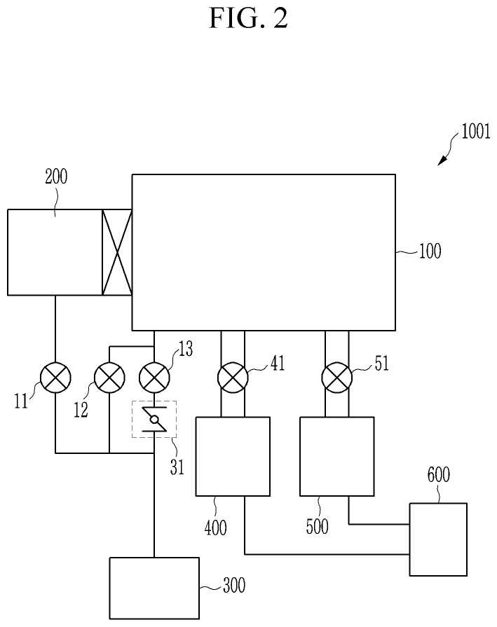

Hereinafter, a deposition apparatus 1001 according to another example will be described with reference to FIG. 2. FIG. 2 illustrates a schematic block diagram of a deposition apparatus according to an embodiment.

The deposition apparatus 1001 of FIG. 2 is similar to the deposition apparatus 1000 of FIG. 1. Detailed description of the same constituent elements will be omitted for descriptive convenience.

The deposition apparatus 1001 according to an embodiment may include a process chamber 100, a cryopump 200 connected to the process chamber 100, a dry pump 300 connected to the process chamber 100, a residual gas analyzer 400 connected to the process chamber 100, a cleansing gas supplier 500 connected to the process chamber 100, and a driver 600 connected to the residual gas analyzer 400 and the cleansing gas supplier 500.

A first valve 11 may be connected between the cryopump 200 and the dry pump 300, and a second valve 12 may be connected between the process chamber 100 and the dry pump 300. For example, a third valve 13 and a pressure control valve 31 may be connected between the process chamber 100 and the dry pump 300. The pressure control valve 31 may be a throttle valve.

Compared to the deposition apparatus 1000 of FIG. 1, the deposition apparatus 1001 of FIG. 2 may further include a fourth valve 41 connected between the process chamber 100 and the residual gas analyzer 400, and a fifth valve 51 connected between the process chamber 100 and the cleansing gas supplier 500.

The fourth valve 41 and the fifth valve 51 may be on-off valves. For example, the fourth valve 41 and the fifth valve 51 may be turned off in case that the cleansing process is not performed. Thus, the residual gas analyzer 400 and the cleansing gas supplier 500 may be separated (or disconnected) from the process chamber 100.

For example, the deposition apparatus 1001 of FIG. 2 according to an embodiment may selectively separate the residual gas analyzer 400 and the cleansing gas supplier 500 from the process chamber 100. Thus, a cleansing process of a predetermined process chamber 100 required among a plurality of process chambers 100 may be performed by using a residual gas analyzer 400 (e.g., a single residual gas analyzer), a cleansing gas supplier 500 (e.g., a single cleansing gas supplier), and a driver 600 (e.g., a single driver), thereby increasing process efficiency. For example, since the residual gas analyzer 400, the cleansing gas supplier 500, and the driver 600 may be separated (or disconnected) from the process chamber 100 for maintenance, the management efficiency of the deposition apparatus may be improved.

In the deposition apparatus 1001 of FIG. 2 according to an embodiment, the residual gas concentration and the like in the process chamber 100 may be measured by using the residual gas analyzer 400, and the driver 600 may use the measured value of the residual gas analyzer 400 to determine whether residual gas is removed or not (or whether removal of the residual gas is necessary). For example, in case that the removal of the residual gas is determined, a removal process of the residual gas using the cleansing gas supplier 500 may be performed. For example, the driver 600 may analyze the measured result of the residual gas analyzer 400 to determine whether to proceed or stop the operation of the cleansing gas supplier 500. For example, the process of monitoring the residual gas inside the process chamber 100 and simultaneously using the result to remove the residual gas through the cleansing gas supplier 500 may be performed in-situ, so that the cleansing process may be quickly and accurately performed.

For example, according to the deposition apparatus 1001 of FIG. 2 according to an embodiment, the inside state of the process chamber 100 may be automatically adjusted to be maintained at a desired pressure during the cleansing process through the pressure control valve 31. Thus, the efficiency of the process of removing residual gas inside the process chamber 100 may be improved.

Many features of the deposition apparatus 1000 of FIG. 1 may be applicable to the deposition apparatus 1001 of FIG. 2 according to an embodiment.

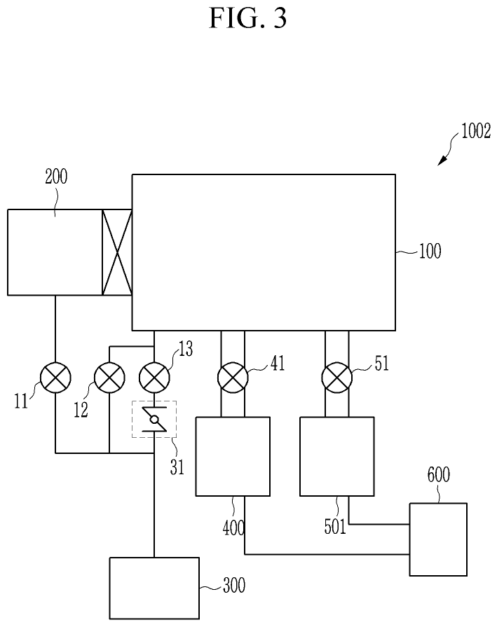

Hereinafter, a deposition apparatus 1002 according to another example will be described with reference to FIG. 3. FIG. 3 illustrates a schematic block diagram of a deposition apparatus according to an embodiment.

Referring to FIG. 3, the deposition apparatus 1002 according to an embodiment is similar to the deposition apparatus 1000 according to an embodiment described with reference to FIG. 1. Detailed description of the same constituent elements will be omitted for descriptive convenience.

The deposition apparatus 1002 according to an embodiment may include a process chamber 100, a cryopump 200 connected to the process chamber 100, a dry pump 300 connected to the process chamber 100, a residual gas analyzer 400 connected to the process chamber 100, a cleansing gas supply device 501 connected to the process chamber 100, and a driver 600 connected to the residual gas analyzer 400 and the cleansing gas supply device 501.

A first valve 11 may be connected between the cryopump 200 and the dry pump 300, and a second valve 12 may be connected between the process chamber 100 and the dry pump 300. For example, a third valve 13 and a pressure control valve 31 may be connected between the process chamber 100 and the dry pump 300. The pressure control valve 31 may be a throttle valve.

Compared to the deposition apparatus 1000 of FIG. 1, the cleansing gas supply device 501 of the deposition apparatus 1002 of FIG. 3 may include an ozone generator and may not include a gas activating device for generating plasma. During the cleansing process, in case that ozone (O₃) is supplied into the process chamber 100 from the cleansing gas supply device 501, the ozone (O₃) may be reduced to oxygen molecules (O₂) and oxygen atoms (O), and at this time, the generated oxygen atoms (O) and hydrocarbons (CₙHₘ), which are organic materials remaining inside the process chamber 100, react to generate gases such as hydrogen (H₂), water (H₂O), and carbon monoxide (CO), and the generated gases may be discharged to the outside of the process chamber 100.

The deposition apparatus 1002 of FIG. 3 according to an embodiment may further include a fourth valve 41 connected between the process chamber 100 and the residual gas analyzer 400 and a fifth valve 51 connected between the process chamber 100 and the cleansing gas supply device 501.

The fourth valve 41 and the fifth valve 51 may be on-off valves. For example, the fourth valve 41 and the fifth valve 51 are turned off in case that the cleansing process is not performed. Thus, the residual gas analyzer 400 and the cleansing gas supply device 501 may be separated (or disconnected) from the process chamber 100.

For example, the deposition apparatus 1002 according to an embodiment may separate the residual gas analyzer 400 and the cleansing gas supply device 501 from the process chamber 100. Thus, a cleansing process of a predetermined process chamber 100 required among a plurality of process chambers 100 may be performed by using a residual gas analyzer 400 (e.g., a single residual gas analyzer), a cleansing gas supply device 501 (e.g., a single cleansing gas supply device), and a driver 600 (e.g., a single driver), thereby increasing process efficiency. For example, since the residual gas analyzer 400, the cleansing gas supply device 501, and the driver 600 may be separated (or disconnected) from the process chamber 100 for maintenance, the management efficiency of the deposition apparatus may be improved.

In the deposition apparatus 1002 of FIG. 3 according to an embodiment, the residual gas concentration and the like in the process chamber 100 may be measured by using the residual gas analyzer 400, and the driver 600 may use the measured value of the residual gas analyzer 400 to determine whether residual gas is removed or not (or whether removal of the residual gas is necessary). For example, in case that the removal of the residual gas is determined, a removal process of the residual gas using the cleansing gas supply device 501 may be performed. For example, the driver 600 may analyze the measured result of the residual gas analyzer 400 to determine whether to proceed or stop the operation of the cleansing gas supply device 501. Thus, the process of monitoring the residual gas inside the process chamber 100 and simultaneously using the result to remove the residual gas through the cleansing gas supply device 501 may be performed in-situ, so that the cleansing process may be quickly and accurately performed.

For example, according to the deposition apparatus 1002 according to an embodiment, the inside state of the process chamber 100 may be automatically adjusted to be maintained at a desired pressure during the cleansing process through the pressure control valve 31. Thus, the efficiency of the process of removing residual gas inside the process chamber 100 may be improved.

Many features of the deposition apparatuses 1000 and 1001 of FIGS. 1 and 2 may be applicable to the deposition apparatus 1002 of FIG. 3 according to an embodiment.

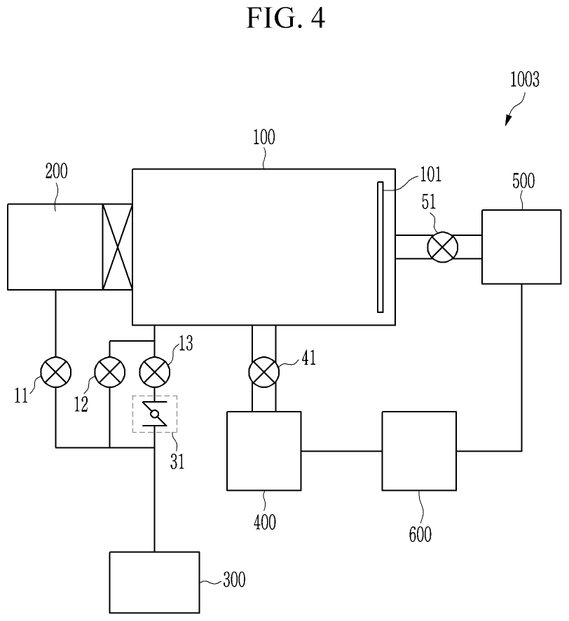

Hereinafter, a deposition apparatus 1003 according to another embodiment will be described with reference to FIG. 4. FIG. 4 illustrates a schematic block diagram of a deposition apparatus according to an embodiment.

Referring to FIG. 4, the deposition apparatus 1003 according to an embodiment is similar to the deposition apparatus 1000 of FIG. 1. Detailed description of the same constituent elements will be omitted for descriptive convenience.

The deposition apparatus 1003 according to an embodiment may include a process chamber 100, a cryopump 200 connected to the process chamber 100, a dry pump 300 connected to the process chamber 100, a residual gas analyzer 400 connected to the process chamber 100, a cleansing gas supplier 500 connected to the process chamber 100, and a driver 600 connected to the residual gas analyzer 400 and the cleansing gas supplier 500.

A first valve 11 may be connected between the cryopump 200 and the dry pump 300, and a second valve 12 may be connected between the process chamber 100 and the dry pump 300. For example, a third valve 13 and a pressure control valve 31 may be connected between the process chamber 100 and the dry pump 300. The pressure control valve 31 may be a throttle valve.

A position of the cleansing gas supplier 500 of the deposition apparatus 1003 of FIG. 4 according to an embodiment may be different from that of the deposition apparatus 1000 of FIG. 1. For example, the cleansing gas supplier 500 may be disposed at a position facing the cryopump 200, and by changing the cleansing gas supplier 500, the cleansing gas supplied from the cleansing gas supplier 500 may be more quickly and uniformly spread.

For example, the deposition apparatus 1003 of FIG. 4 according to an embodiment may further include a fourth valve 41 connected between the process chamber 100 and the residual gas analyzer 400, and a fifth valve 51 connected between the process chamber 100 and the cleansing gas supplier 500.

The fourth valve 41 and the fifth valve 51 may be on-off valves. For example, the fourth valve 41 and the fifth valve 51 are turned off in cast that the cleansing process is not performed. Thus, the residual gas analyzer 400 and the cleansing gas supplier 500 may be separated (or disconnected) from the process chamber 100.

For example, the deposition apparatus 1003 of FIG. 4 according to an embodiment may separate the residual gas analyzer 400 and the cleansing gas supplier 500 from the process chamber 100. Thus, a cleansing process of a predetermined process chamber 100 required among a plurality of process chambers 100 may be performed by using a residual gas analyzer 400 (e.g., a single residual gas analyzer), a cleansing gas supplier 500 (e.g., a single cleansing gas supplier), and a driver 600 (e.g., a single driver), thereby increasing process efficiency.

In the deposition apparatus 1003 according to an embodiment, the residual gas concentration and the like in the process chamber 100 may be measured by using the residual gas analyzer 400, and the driver 600 may use the measured value of the residual gas analyzer 400 to determine whether residual gas is removed or not (or whether removal of the residual gas is necessary). For example, in case that the removal of the residual gas is determined, a removal process of the residual gas using the cleansing gas supplier 500 may be performed. For example, the driver 600 may analyze the measured result of the residual gas analyzer 400 to determine whether to proceed or stop the operation of the cleansing gas supplier 500. Thus, the process of monitoring the residual gas inside the process chamber 100 and simultaneously using the result to remove the residual gas through the cleansing gas supplier 500 may be performed in-situ, so that the cleansing process may be quickly and accurately performed.

For example, according to the deposition apparatus 1003 according to an embodiment, the inside state of the process chamber 100 may be automatically adjusted to be maintained at a desired pressure during the cleansing process through the pressure control valve 31. Thus, the efficiency of the process of removing residual gas inside the process chamber 100 may be improved.

Many features of the deposition apparatuses 1000, 1001, and 1002 of FIGS. 1, 2, and 3 may be applicable to the deposition apparatus 1003 of FIG. 4 according to an embodiment.

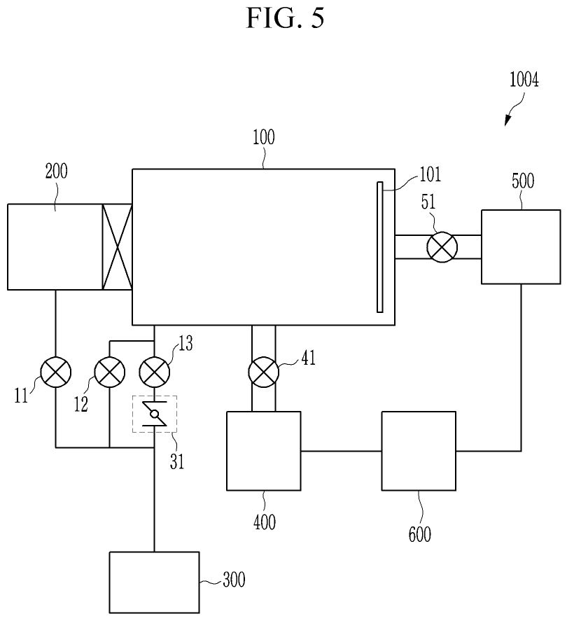

Hereinafter, a deposition apparatus 1004 according to another example will be described with reference to FIG. 5. FIG. 5 illustrates a schematic block diagram of a deposition apparatus according to an embodiment.

Referring to FIG. 5, the deposition apparatus 1004 according to an embodiment is similar to the deposition apparatus 1000 according to an embodiment described with reference to FIG. 1. Detailed description of the same constituent elements will be omitted for descriptive convenience.

The deposition apparatus 1004 according to an embodiment may include a process chamber 100, a cryopump 200 connected to the process chamber 100, a dry pump 300 connected to the process chamber 100, a residual gas analyzer 400 connected to the process chamber 100, a cleansing gas supplier 500 connected to the process chamber 100, and a driver 600 connected to the residual gas analyzer 400 and the cleansing gas supplier 500.

A first valve 11 may be connected between the cryopump 200 and the dry pump 300, and a second valve 12 may be connected between the process chamber 100 and the dry pump 300. For example, a third valve 13 and a pressure control valve 31 may be connected between the process chamber 100 and the dry pump 300. The pressure control valve 31 may be a throttle valve.

A position of the cleansing gas supplier 500 of the deposition apparatus 1004 of FIG. 5 according to an embodiment may be different from that of the deposition apparatus 1000 of FIG. 1. For example, the cleansing gas supplier 500 may be disposed at a position facing the cryopump 200, and by changing the cleansing gas supplier 500, the cleansing gas supplied from the cleansing gas supplier 500 may be more quickly and uniformly spread.

For example, the deposition apparatus 1004 of FIG. 5 according to an embodiment may further include a baffle 101 disposed adjacent to the cleansing gas supplier 500. The baffle 101 may be disposed inside the process chamber 100. The baffle 101 may flow the cleansing gas supplied from the cleansing gas supplier 500 in a horizontal direction or a vertical direction. Thus, the cleansing gas supplied from the cleansing gas supplier 500 may be more quickly and uniformly spread.

For example, the deposition apparatus 1004 of FIG. 5 according to an embodiment may further include a fourth valve 41 connected between the process chamber 100 and the residual gas analyzer 400, and a fifth valve 51 connected between the process chamber 100 and the cleansing gas supplier 500.

The fourth valve 41 and the fifth valve 51 may be on-off valves. For example, the fourth valve 41 and the fifth valve 51 are turned off in case that the cleansing process is not performed. Thus, the residual gas analyzer 400 and the cleansing gas supplier 500 may be separated (or disconnected) from the process chamber 100.

For example, the deposition apparatus 1004 according to an embodiment may separate the residual gas analyzer 400 and the cleansing gas supplier 500 from the process chamber 100. Thus, a cleansing process of a predetermined process chamber 100 required among a plurality of process chambers 100 may be performed by using a residual gas analyzer 400 (e.g., a single residual gas analyzer), a cleansing gas supplier 500 (e.g., a single cleansing gas supplier), and a driver 600 (e.g., a single driver), thereby increasing process efficiency.

In the deposition apparatus 1004 according to an embodiment, the residual gas concentration and the like in the process chamber 100 may be measured by using the residual gas analyzer 400, and the driver 600 may use the measured value of the residual gas analyzer 400 to determine whether residual gas is removed or not (or whether removal of the residual gas is necessary). For example, in case that the removal of the residual gas is determined, a removal process of the residual gas using the cleansing gas supplier 500 may be performed. For example, the driver 600 may analyze the measured result of the residual gas analyzer 400 to determine whether to proceed or stop the operation of the cleansing gas supplier 500. Thus, the process of monitoring the residual gas inside the process chamber 100 and simultaneously using the result to remove the residual gas through the cleansing gas supplier 500 may be performed in-situ, so that the cleansing process may be quickly and accurately performed.

For example, according to the deposition apparatus 1004 of FIG. 5 according to an embodiment, the inside state of the process chamber 100 may be automatically adjusted to be maintained at a desired pressure during the cleansing process through the pressure control valve 31. Thus, the efficiency of the process of removing residual gas inside the process chamber 100 may be improved.

Many features of the deposition apparatuses 1000, 1001, 1002, and 1003 of FIGS. 1, 2, 3, and 4 may be applicable to the deposition apparatus 1004 of FIG. 5 according to an embodiment.

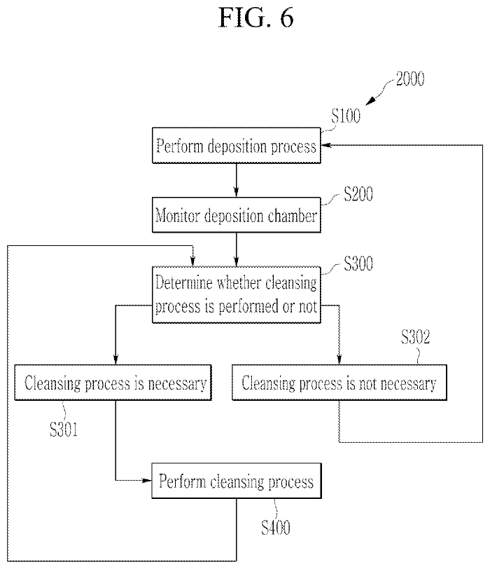

Referring to FIG. 6, a method 2000 of cleansing the deposition apparatus according to an embodiment will be described with FIGS. 1, 2, 3, 4, and 5. FIG. 6 illustrates a flowchart illustrating a method of cleansing a deposition apparatus according to an embodiment.

The method 2000 of cleansing the deposition apparatus according to an embodiment may include a step (S100) of performing a deposition process, and a step (S200) of monitoring (or measuring) the presence and concentration of residual gas in the process chamber 100 by using the residual gas analyzer 400 connected to the process chamber 100 before or after the step (S100) of performing the deposition process.

For example, the presence and concentration of the residual gas in the process chamber 100 may be measured by using the residual gas analyzer 400 connected to the process chamber 100, and a measurement result of the residual gas analyzer 400 may be transmitted to the driver 600.

The method 2000 of cleansing the deposition apparatus according to an embodiment may include a step (S300) of determining whether a cleansing process of the process chamber 100 is performed or not (or whether the cleansing process of the process chamber 100 is necessary) by the driver 600 based on the measurement result of the residual gas analyzer 400 received by the driver 600.

In case that it is determined that the cleansing process of the process chamber 100 is necessary (S301) in the step (S300) of determining whether the cleansing process of the process chamber 100 is performed or not (or whether the cleansing process of the process chamber 100 is necessary), the method 2000 of cleansing the deposition apparatus according to an embodiment may include a step (S400) of performing the cleansing process of the process chamber 100. The step (S400) of performing the cleansing process of the process chamber 100 may include a step (S400) of supplying a cleansing gas to the process chamber 100 by using the cleansing gas supplier 500 to react the cleansing gas with the residual gas in the process chamber 100 to remove contaminants in the process chamber 100.

After the step (S400) of removing the contaminants in the process chamber 100, the step (S200) of monitoring (or measuring) the presence and concentration of the residual gas in the process chamber 100 may be continued by using the residual gas analyzer 400.

In case that it is determined that the cleansing process of the process chamber 100 is not necessary (S302) in the step (S300) of determining whether the cleansing process of the process chamber 100 is performed or not (or whether the cleansing process of the process chamber 100 is necessary), the operation of the cleansing gas supplier 500 may be stopped, and the step (S100) of performing the deposition process may be performed again.

In the step (S400) of removing the contaminants in the process chamber 100 by using the cleansing gas supplier 500, the cleansing gas supplier 500 may be a gas activating device, and the cleansing gas supplier 500 may generate plasma. The cleansing gas supplier 500 may generate oxygen radicals and supply the oxygen radicals into the process chamber 100. The cleansing gas supplied from the cleansing gas supplier 500 may be a mixture of nitrogen (N₂) and an inert gas such as argon (Ar) together with oxygen radicals.

The oxygen radicals supplied into the process chamber 100 from the cleansing gas supplier 500 react with a hydrocarbon (CₙHₘ), which is an organic material remaining inside the process chamber 100, and thus gases such as hydrogen (H₂), water (H₂O), and carbon monoxide (CO) may be generated, and the generated gases may be discharged to the outside of the process chamber 100.

In the step (S400) of removing the contaminants in the process chamber 100 by using the cleansing gas supplier 500, the cleansing gas supplier 500 may be an ozone generator, and the cleansing gas supplier 500 may generate ozone. In case that ozone (O₃) is supplied into the process chamber 100 from the cleansing gas supply device 501, the ozone (O₃) may be reduced to oxygen molecules (O₂) and oxygen atoms (O), and at this time, the generated oxygen atoms (O) and hydrocarbons (CₙHₘ), which are organic materials remaining inside the process chamber 100, react to generate gases such as hydrogen (H₂), water (H₂O), and carbon monoxide (CO), and the generated gases may be discharged to the outside of the process chamber 100.

During the step (S400) of removing the contaminants in the process chamber 100 by using the cleansing gas supplier 500, the inside state of the process chamber 100 may be maintained at a desired pressure during the cleansing process by using the pressure control valve 31 positioned between the third valve 13 and the dry pump 300.

According to the method 2000 of cleansing the deposition apparatus according to an embodiment, the step (S400) of removing the contaminants in the process chamber 100 may be performed by using the cleansing gas supplier 500, and the step (S300) of determining whether the cleansing process of the process chamber 100 is performed or not (or whether the cleansing process of the process chamber 100 is necessary) may be subsequently performed by the driver 600 by using the measurement result of the residual gas analyzer 400. As described above, in case that the residual gas removing step using the cleansing gas supplier 500 is performed, the driver 600 may use (or control) the residual gas analyzer 400 to measure the residual gas in the process chamber 100, so that the driver 600 may maintain an operation of the cleansing gas supplier 500 in case that a concentration of the residual gas in the process chamber 100 is larger than or equal to a predetermined value based on data (e.g., the measured result) received from the residual gas analyzer 400. Further, the operation of the cleansing gas supplier 500 may be stopped in case that the concentration of the residual gas in the process chamber 100 is smaller than a predetermined value, thereby stopping the chamber cleansing process.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus comprising:
a process chamber;
a residual gas analyzer connected to the process chamber;
a cleansing gas supplier connected to the process chamber; and
a driver connected to the residual gas analyzer and the cleansing gas supplier, the driver that controls the residual gas analyzer and the cleansing gas supplier.

2. The deposition apparatus of claim 1, wherein the driver controls an operation of the cleansing gas supplier based on data received from the residual gas analyzer.

3. The deposition apparatus of claim 2, further comprising:
a dry pump connected to the process chamber; and
a pressure control valve connected between the process chamber and the dry pump.

4. The deposition apparatus of claim 3, further comprising:
an on-off valve connected between the process chamber and the pressure control valve.

5. The deposition apparatus of claim 3, further comprising:
a first valve connected between the process chamber and the residual gas analyzer; and
a second valve connected between the process chamber and the cleansing gas supplier.

6. The deposition apparatus of claim 5, wherein the residual gas analyzer and the cleansing gas supplier are connected to or disconnected from the process chamber by the first valve and the second valve.

7. The deposition apparatus of claim 2, wherein the residual gas analyzer and the cleansing gas supplier are connected to a side of the process chamber.

8. The deposition apparatus of claim 7, further comprising:
a baffle adjacent to the cleansing gas supplier.

9. The deposition apparatus of claim 2, wherein the cleansing gas supplier is a plasma generator.

10. The deposition apparatus of claim 9, wherein the cleansing gas supplier supplies oxygen radicals.

11. The deposition apparatus of claim 2, wherein the cleansing gas supplier is an ozone generator.

12. A method of cleansing a deposition apparatus, the method comprising:
measuring a concentration of a residual gas in a process chamber;
determining, by a driver, whether a cleansing process of the process chamber is performed based on the measured concentration of the residual gas;
supplying a cleansing gas to the process chamber to cleanse the process chamber; and
re-measuring a concentration of the residual gas in the cleansed process chamber.

13. The method of cleansing the deposition apparatus of claim 12, further comprising:
transmitting the measured concentration of the residual gas to the driver.

14. The method of cleansing the deposition apparatus of claim 13, wherein in case that the driver determines to perform the cleansing process, the cleansing process of the process chamber and the re-measuring of the concentration of the residual gas in the cleansed process chamber are performed.

15. The method of cleansing the deposition apparatus of claim 13, wherein in case that the driver determines not to perform the cleansing process, the cleansing process of the process chamber and the re-measuring of the concentration of the residual gas in the cleansed process chamber are stopped.

16. The method of cleansing the deposition apparatus of claim 13, wherein the supplying of the cleansing gas includes supplying oxygen radicals to the process chamber.

17. The method of cleansing the deposition apparatus of claim 16, wherein the supplying of the cleansing gas includes supplying an inert gas.

18. The method of cleansing the deposition apparatus of claim 17, wherein the inert gas includes nitrogen gas or argon.

19. The method of cleansing the deposition apparatus of claim 13, wherein the supplying of the cleansing gas includes supplying ozone to the process chamber.

20. The method of cleansing the deposition apparatus of claim 13, wherein a pressure of the process chamber is maintained to be substantially constant during the cleansing process of the process chamber by a pressure control valve connected between the process chamber and a dry pump.
